(19) United States
(12) Patent Application Publication
(10) Pub. No.: US 2024/0105900 A1
(43) Pub. Date: Mar. 28, 2024

(54) DISPLAY DEVICE

(71) Applicant: Samsung Display Co., LTD., Yongin-si (KR)

(72) Inventors: Sang Yong NO, Yongin-si (KR); Sun Kwun SON, Yongin-si (KR); Dong Hee SHIN, Yongin-si (KR)

(21) Appl. No.: 18/475,026

(22) Filed: Sep. 26, 2023

(30) Foreign Application Priority Data
Sep. 28, 2022 (KR) 10-2022-0123573

(51) Int. Cl. H01L 33/62; H01L 25/075; H01L 25/16; H01L 27/12

(52) U.S. Cl. CPC H01L 33/62; H01L 25/0753; H01L 25/167; H01L 27/124

(57) ABSTRACT

A display device includes a substrate, a first semiconductor layer, and including first and second transistors, first and second gate conductive layers above the first semiconductor layer, a second semiconductor layer above the second gate conductive layer, and including a third transistor, a third gate conductive layer above the second semiconductor layer, an insulating film defining a valley surrounding the first semiconductor layer, the first gate conductive layer, the second gate conductive layer, the second semiconductor layer, and the third gate conductive layer, a connection metal conductive layer above the insulating film, and including a first connection electrode electrically connecting the first and third transistors, the first connection electrode including a (1-1)-th region overlapping the first transistor, and a (1-2)-th region and a (1-3)-th region overlapping the third transistor and connected to the third transistor, and first and second data conductive layers above the connection metal conductive layer.

### CROSS-REFERENCE TO RELATED APPLICATION

This application claims priority to, and the benefit of, Korean Patent Application No. 10-2022-0123573 filed in the Korean Intellectual Property Office on Sep. 28, 2022, the entire contents of which are incorporated herein by reference.

### BACKGROUND

### 1. Field

The present disclosure relates to a display device.

### 2. Description of the Related Art

A display device is a device for displaying an image, and includes a liquid crystal display (LCD), an organic light-emitting diode (OLED) display, and the like. The display device is used in various electronic devices, such as a mobile phone, a navigation device, a digital camera, an electronic book, a portable game machine, and various terminals.

A display device, such as the organic light-emitting diode display may have a structure in which the display device is bent or folded using a flexible substrate.

The above information disclosed in this Background section is only for enhancement of understanding of the background of the present disclosure, and therefore may contain information that does not form the prior art that is already known in this country to a person of ordinary skill in the art.

### SUMMARY

Embodiments provide a display device with improved display quality while reducing an influence caused by an external impact.

A display device according to one or more embodiments includes a substrate, a first semiconductor layer above the substrate, and including a first transistor and a second transistor, a first gate conductive layer and a second gate conductive layer above the first semiconductor layer, a second semiconductor layer above the second gate conductive layer, and including a third transistor, a third gate conductive layer above the second semiconductor layer, an insulating film defining a valley surrounding the first semiconductor layer, the first gate conductive layer, the second gate conductive layer, the second semiconductor layer, and the third gate conductive layer, a connection metal conductive layer above the insulating film, and including a first connection electrode electrically connecting the first transistor to the third transistor, the first connection electrode including a (1-1)-th region overlapping the first transistor, and a (1-2)-th region and a (1-3)-th region overlapping the third transistor, the (1-2)-th region and the (1-3)-th region being connected to the third transistor, and a first data conductive layer and a second data conductive layer above the connection metal conductive layer.

The first connection electrode may include a first connection region connecting the (1-1)-th region and the (1-2)-th region, wherein the (1-3)-th region protrudes from the first connection region.

The (1-2)-th region and the (1-3)-th region may be spaced apart from each other.

The (1-2)-th region and the (1-3)-th region may protrude in a first direction, wherein the first connection region extends in a second direction that is substantially perpendicular to the first direction.

The third transistor may include a first region, a second region, and a channel between the first region and the second region, wherein the (1-2)-th region and the (1-3)-th region are electrically connected to the second region of the third transistor.

The (1-2)-th region and the (1-3)-th region may be connected to the third transistor through an opening.

The (1-2)-th region and the (1-3)-th region may be spaced apart from the second gate conductive layer and the third gate conductive layer.

The connection metal conductive layer may further include a twelfth connection electrode that includes a (2-1)-th region and a (2-2)-th region overlapping the second transistor, and that includes a second connection region between the (2-1)-th region and the (2-2)-th region.

The second transistor may include a first region, a second region, and a channel between the first region and the second region, wherein the (2-1)-th region and the (2-2) region overlap the second region of the second transistor.

The (2-1)-th region and the (2-2)-th region may be connected to the second region of the second transistor through an opening.

The second connection region may be spaced apart from the second transistor.

The second transistor may further include a protrusion overlapping the (2-1)-th region and the (2-2)-th region.

The connection metal conductive layer may include at least one of gold (Au), silver (Ag), aluminum (Al), copper (Cu), platinum (Pt), and iron (Fe).

A display device according to one or more other embodiments includes a substrate, a first semiconductor layer above the substrate, and including a first transistor and a second transistor, a first gate conductive layer and a second gate conductive layer above the first semiconductor layer, a second semiconductor layer above the second gate conductive layer, and including a third transistor that includes a first region, a second region, and a channel, a third gate conductive layer above the second semiconductor layer, an insulating film that includes a valley surrounding the first semiconductor layer, the first gate conductive layer, the second gate conductive layer, the second semiconductor layer, and the third gate conductive layer, a connection metal conductive layer above the insulating film, and including a first connection electrode electrically connecting the first transistor to the third transistor, the first connection electrode including a (1-1)-th region overlapping the first transistor and a (1-2)-th region covering the second region of the third transistor, and a first data conductive layer and a second data conductive layer above the connection metal conductive layer.

The first connection electrode may include a first connection region connecting the (1-1)-th region and the (1-2)-th region, and extending in a first direction, wherein the (1-2)-th region and the first connection region extend in a second direction that is substantially perpendicular to the first direction.

The third transistor may include the channel between the first region and the second region, wherein the (1-2)-th region is electrically connected to the second region of the third transistor through at least two openings.

The (1-2)-th region may be spaced apart from the second gate conductive layer and the third gate conductive layer.

The connection metal conductive layer may further include a twelfth connection electrode that includes a (2-1)-th region and a (2-2)-th region overlapping the second transistor, and a second connection region between the (2-1)-th region and the (2-2)-th region.

The second transistor may include a first region, a second region, and a channel between the first region and the second region, wherein the (2-1)-th region and the (2-2)-th region are connected to the second region of the second transistor through an opening.

The second connection region may overlap the second transistor.

According to the embodiments, the display quality of the display device may be improved while reducing the influence of the external impact.

### BRIEF DESCRIPTION OF THE DRAWINGS

FIG. 1 is a schematic perspective view illustrating a use state of a display device according to one or more embodiments.

FIG. 2 is an exploded perspective view of the display device according to one or more embodiments.

FIG. 3 is a block diagram of the display device according to one or more embodiments.

FIG. 4 is a perspective view schematically illustrating a display device according to one or more other embodiments.

FIG. 5 is a circuit diagram of one pixel included in the display device according to one or more embodiments.

FIGS. 6 to 16 are views illustrating in detail a structure of each layer according to a process of manufacturing a display panel layer of the display device according to one or more embodiments.

FIG. 17 is a cross-sectional view of the display panel layer of FIG. 16.

FIG. 18 is a plan view of a display panel layer according to one or more other embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” The electronic or electric devices and/or any other relevant devices or

components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

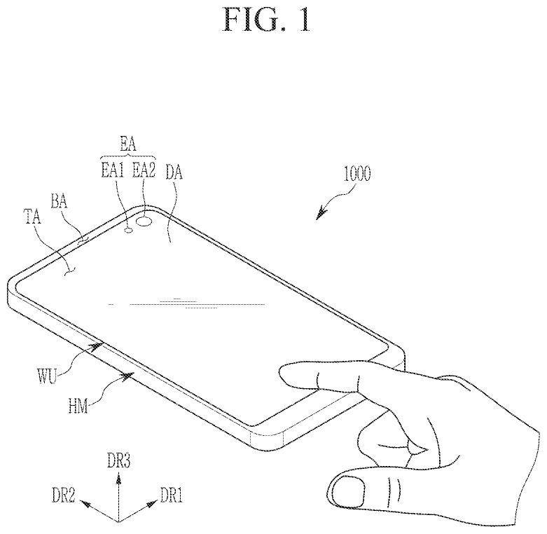

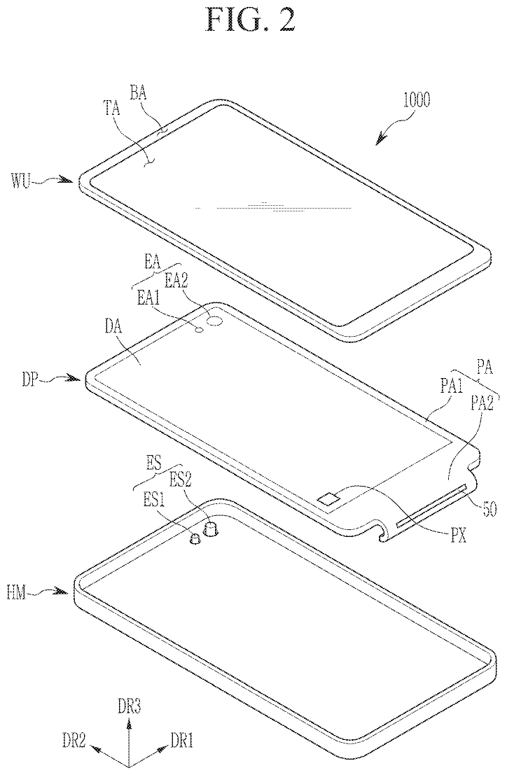

Hereinafter, a schematic structure of a display device will be described with reference to FIGS. 1 to 3. FIG. 1 is a schematic perspective view illustrating a use state of the display device according to one or more embodiments. FIG. 2 is an exploded perspective view of the display device according to one or more embodiments.

Referring to FIG. 1, the display device 1000 according to one or more embodiments may be a device that displays a moving image or a still image, and may be used for a display screen for a portable electronic device, such as a mobile phone, a smart phone, a tablet personal computer (PC), a mobile communication terminal, an electronic note, an electronic book, a portable multimedia player (PMP), a navigation device, an ultra-mobile PC (UMPC), or the like, and various products, such as a television, a laptop computer, a monitor, a billboard, the Internet of things (IOT), and the like. In addition, the display device 1000 may be used in a wearable device, such as a smart watch, a watch phone, a glass-type display, and a head mounted display (HMD). In addition, the display device 1000 may be used as a center information display (CID) located at a dashboard and a center fascia of a vehicle, a room mirror display in place of a side mirror of a vehicle, an entertainment for a rear seat of a vehicle, or a display located at a back of a front seat of a vehicle. FIG. 1 illustrates that the display device 1000 is used as a smartphone, for convenience of description.

The display device 1000 may display an image in a third direction DR3 at a display surface parallel to a first direction DR1 and a second direction DR2. The display surface on which the image is displayed may correspond to a front surface of the display device 1000, and may correspond to a front surface of a cover window WU. The image may include a still image as well as a dynamic image.

A front surface (or an upper surface) and a rear surface (or a lower surface) of each member are defined based on a direction in which the image is displayed. The front surface and the rear surface may be opposed to each other in the third direction DR3, and a normal direction of each of the front surface and the rear surface may be parallel to the third direction DR3. A separation distance between the front surface and the rear surface in the third direction DR3 may correspond to a thickness of a display panel in the third direction DR3.

The display device 1000 may detect an input (e.g., an input by a hand of FIG. 1) of a user applied from the outside. The user's input may include various types of external inputs, such as a portion of the user's body, light, heat, pressure, and the like. In FIG. 1, the user's input is illustrated by the user's hand applied to the front surface. However, the present disclosure is not limited thereto. The user's input may be provided in various forms, and the display device 1000 may sense the user's input applied to a side surface or a rear surface of the display device 1000 according to a structure of the display device 1000.

Referring to FIGS. 1 and 2, the display device 1000 may include the cover window WU, a housing HM, a display panel DP, and an optical element ES. In one or more embodiments, the cover window WU and the housing HM may be coupled to form an appearance of the display device 1000.

The cover window WU may include an insulating panel. For example, the cover window WU may be made of glass, plastic, or a combination thereof.

A front surface of the cover window WU may define the front surface of the display device 1000. A transmission area TA may be an optically transparent area. For example, the transmission area TA may be an area having a visible light transmittance of about 90% or more.

A blocking area BA may define a shape of the transmission area TA. The blocking area BA may be adjacent to the transmission area TA and may surround the transmission area TA. The blocking area BA may be an area having relatively low light transmittance compared to the transmission area TA. The blocking area BA may include an opaque material that blocks light. The blocking area BA may have a color (e.g., a predetermined color). The blocking area BA may be defined by a bezel layer provided separately from a transparent substrate defining the transmission area TA, or may be defined by an ink layer formed by being inserted into or colored on a transparent substrate.

The display panel DP may include a display area DA for displaying an image, and a driver 50. The display panel DP may include a front surface including the display area DA and a non-display area PA. The display area DA may be an area in which a pixel operates according to an electrical signal to emit a light.

In one or more embodiments, the display area DA may be an area in which an image is displayed by including the pixel, and may be an area in which an external input is sensed by a touch sensor positioned above the pixel in the third direction DR3.

The transparent area TA of the cover window WU may at least partially overlap the display area DA of the display panel DP. For example, the transmission area TA may overlap an entire surface of the display area DA or may overlap at least a portion of the display area DA. Accordingly, the user may view the image through the transmission area TA or may provide an external input based on the image. However, the present disclosure is not limited thereto. For example, an area in which the image is displayed in the display area DA and an area in which the external input is detected may be separated from each other.

The non-display area PA of the display panel DP may at least partially overlap the blocking area BA of the cover window WU. The non-display area PA may be an area covered by the blocking area BA. The non-display area PA may be adjacent to the display area DA and may surround the display area DA. An image may not be displayed at the non-display area PA, and a driving circuit, driving wiring, or the like for driving the display area DA may be located. The non-display area PA may include a first peripheral area PA1 positioned outside the display area DA, and a second peripheral area PA2 including the driver 50, connection wiring, and a bending area. In FIG. 2, the first peripheral area PA1 is positioned at three sides of the display area DA, and the second peripheral area PA2 is positioned at a remaining side of the display area DA (e.g., with respect to plan view).

In one or more embodiments, the display panel DP may be assembled in a flat state in which the display area DA and the non-display area PA face the cover window WU. However, the present disclosure is not limited thereto. A portion of the non-display area PA of the display panel DP may be bent. In this case, a portion of the non-display area PA may face the rear surface of the display device 1000 so that the blocking area BA shown on the front surface of the display device 1000 is reduced, and in FIG. 2, the second peripheral area PA2 may be bent to be positioned at a rear surface of the display area DA, and then the bent second peripheral area may be assembled at the rear surface of the display area.

In addition, the display panel DP may include a component area EA, and for example, may include a first component area EA1 and a second component area EA2. The first component area EA1 and the second component area EA2 may be at least partially surrounded by the display area DA. Although the first component area EA1 and the second component area EA2 are illustrated as being spaced apart from each other, the present disclosure is not limited thereto, and at least a portion of the first component area may be connected to at least a portion of the second component area. The first component area EA1 or the second component area EA2 may be an area in which a component using infrared light, visible light, sound, or the like is located thereunder.

The display area DA includes a plurality of light-emitting diodes and a plurality of pixels for generating and transmitting a light-emitting current to each of the light-emitting diodes.

The first component area EA1 may include a transmission portion through which light is transmitted, and a second display portion including a plurality of pixels.

The transmission portion included in the first component area EA1 may have a structure in which a conductive layer or a semiconductor layer is not positioned, and a pixel defining layer including a light-blocking material, a light-blocking layer, or the like forms an opening not to block light. The transmission portion of the first component area EA1 represents an area in which the conductive layer or the semiconductor layer is not positioned between adjacent pixels. The first component area EA1 may include the second display portion including the pixels adjacent to the transmission portion.

The second component area EA2 may include a transmission portion through which light and/or sound is transmitted, and a display portion including a plurality of pixels. The transmission portion is positioned between adjacent pixels and includes a transparent layer through which light and/or sound is transmitted. The display portion may be formed to have one unit structure by combining a plurality of pixels, and the transmission portion may be positioned between adjacent unit structures.

Here, each of the display area DA and the first component area EA may include a plurality of pixels. The pixel PX includes one light-emitting diode and one pixel circuit. In the display area DA and the first component area EA, one pixel circuit is formed on a one-to-one basis with respect to one light-emitting diode.

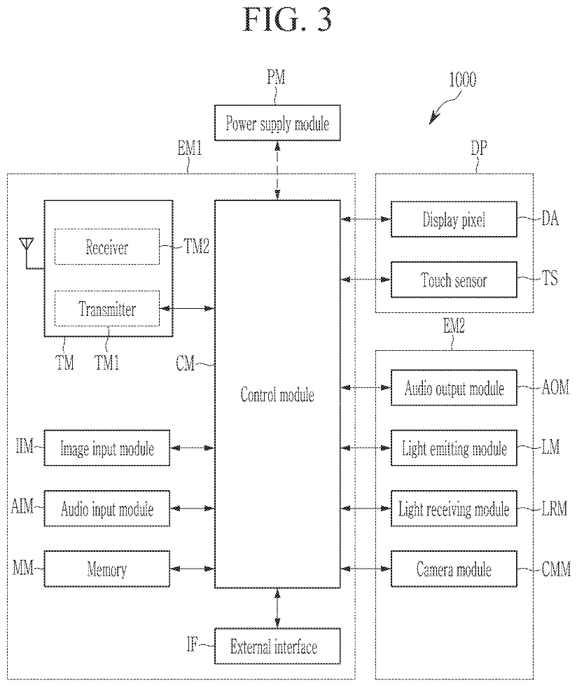

Referring to FIG. 1, FIG. 2, and FIG. 3, the display panel DP may include the display area DA including a display pixel and the touch sensor TS. The display panel DP may include a pixel that is a component that generates an image so that the display panel is visually recognized by the user from the outside through the transmission area TA. In addition, the touch sensor TS may be positioned above the pixel, and may sense an external input applied from the outside. The touch sensor TS may detect the external input provided to the cover window WU.

Referring to FIG. 2, the second peripheral area PA2 may include a bending portion. The display area DA and the first peripheral area PA1 may have a flat state that is substantially parallel to a plane defined by the first direction DR1 and the second direction DR2, and one side of the second peripheral area PA2 may extend from a flat state to have a flat state again after going through the bending portion. As a result, at least a portion of the second peripheral area PA2 may be bent and assembled to be positioned at a rear surface of the display area DA. When at least a portion of the second peripheral area PA2 is assembled, the blocking area BA of the display device 1000 may be reduced because at least a portion of the second peripheral area PA2 overlaps the display area DA on a plane. However, the present disclosure is not limited thereto. For example, the second peripheral area PA2 may not be bent.

The driver 50 may be mounted on the second peripheral area PA2, and may be mounted on the bending portion or may be positioned at one of both sides of the bending portion. The driver 50 may be provided in a form of a chip.

The driver 50 may be electrically connected to the display area DA to transmit an electrical signal to the display area DA. For example, the driver 50 may provide data signals to pixels PX located in the display area DA. Alternatively, the driver 50 may include a touch driving circuit and may be electrically connected to the touch sensor TS located in the display area DA. In addition to the above-described circuit, the driver 50 may include various circuits or may be designed to provide various electrical signals to the display area DA.

A pad part may be positioned at an end of the second peripheral area PA2 of the display device 1000, and the pad part may be electrically connected to a flexible printed circuit board (FPCB) including a driving chip. Here, the driving chip positioned at the flexible printed circuit board may include various driving circuits for driving the display device 1000, a connector for power supply, or the like. According to one or more embodiments, a rigid printed circuit board (PCB) may be used instead of the flexible printed circuit board.

The optical element ES may be located below the display panel DP. The optical element ES may include a first optical element ES1 overlapping the first component area EA1, and a second optical element ES2 overlapping the second component area EA2.

The first optical element ES1 may be an electronic element using light or sound. For example, the first optical element ES1 may be a sensor (e.g., an infrared sensor) that receives and uses light, a sensor that outputs and senses light or sound to measure a distance or that recognizes a fingerprint and the like, a small lamp that outputs light, a speaker that outputs sound, or the like. The electronic element using light may use light of various wavelength bands, such as visible light, infrared light, ultraviolet light, and the like.

The second optical element ES2 may be at least one of a camera, an infrared camera, a dot projector, an infrared illuminator, and a time-of-light sensor.

Referring to FIG. 3, the display device 1000 may include the display panel DP, a power supply (e.g., a power supply module) PM, a first electronic module EM1, and a second electronic module EM2. The display panel DP, the power supply PM, the first electronic module EM1, and the second electronic module EM2 may be electrically connected to each other. In FIG. 3, the display pixel positioned at the display area DA and the touch sensor TS among configurations of the display panel DP are illustrated as examples.

The power supply PM may supply power required for overall operation of the display device 1000. The power supply PM may include a typical battery or battery module.

The first electronic module EM1 and the second electronic module EM2 may include various functional modules for operating the display device 1000. The first electronic module EM1 may be directly mounted on a motherboard electrically connected to the display panel DP or may be mounted on a separate substrate to be electrically connected to the motherboard through a connector and the like.

The first electronic module EM1 may include a control circuit (e.g., a control module) CM, a wireless communicator (e.g., a wireless communication module) TM, an image receiver (e.g., an image input module) IIM, an audio receiver (e.g., an audio input module) AIM, a memory MM, and an external interface IF. Some of the modules and components are not mounted on the motherboard, and may be electrically connected to the motherboard through a flexible printed circuit board connected thereto.

The control circuit CM may control an overall operation of the display device 1000. The control circuit CM may be a microprocessor. For example, the control circuit CM activates or deactivates the display panel DP. The control circuit CM may control other components or modules, such as the image receiver IIM, the audio receiver AIM, and the like based on a touch signal received from the display panel DP.

The wireless communicator TM may transmit/receive a wireless signal to/from another terminal using Bluetooth or Wi-Fi. The wireless communicator TM may transmit/receive a voice signal using a general communication line. The wireless communicator TM includes a transmitter TM1 that modulates and transmits a signal to be transmitted, and a receiver TM2 that demodulates the received signal.

The image receiver IIM may process an image signal to convert the processed image signal to image data displayable on the display panel DP. The audio receiver AIM may receive an external sound signal by a microphone in a recording mode, a voice recognition mode, and the like to convert the received external audio signal to electrical voice data.

The external interface IF may serve as an interface connected to an external charger, a wired/wireless data port, a card socket (e.g., a memory card or a SIM/UIM card), or the like.

The second electronic module EM2 may include an audio transmitter (e.g., an audio output module) AOM, a light transmitter (e.g., a light-emitting module) LM, a light receiver (e.g., a light-receiving module) LRM, a camera (e.g., a camera module) CMM, and the like, and at least some of the audio transmitter, the light transmitter, the light receiver, the camera, and the like that are optical elements ES may be positioned at a rear surface of the display panel DP as shown in FIGS. 1 and 2. The optical elements ES may include the light transmitter LM, the light receiver LRM, the camera CMM, and the like. In addition, the second electronic module EM2 may be directly mounted on the motherboard, may be mounted on a separate substrate to be electrically connected to the display panel DP through a connector and the like, or may be electrically connected to the first electronic module EM1.

The audio transmitter AOM may convert audio data (or sound data) received from the wireless communicator TM or audio data stored in the memory MM to output the converted audio data to the outside.

The light transmitter LM may generate and output light. The light transmitter LM may output infrared light. For example, the light transmitter LM may include an LED element. For example, the light receiver LRM may detect infrared light. The light receiver LRM may be activated when infrared light of a level (e.g., a predetermined level) or more is detected. The light receiver LRM may include a complementary metal-oxide-semiconductor (CMOS) sensor. After the infrared light generated by the light transmitter LM is output, the output infrared light may be reflected by an external subject (e.g., the user's finger or face), and the reflected infrared light may be incident on the light receiver LRM. The camera CMM may capture an external image.

In one or more embodiments, the optical element ES may additionally include a light-sensing sensor or a thermal-sensing sensor. The optical element ES may detect an external subject received through a front surface thereof, or may provide a sound signal, such as voice or the like through the front surface to the outside. In addition, the optical element ES may include a plurality of components, and is not limited to any one embodiment.

Referring again to FIG. 2, the housing HM may be coupled to the cover window WU. The cover window WU may be located at a front surface of the housing HM. The housing HM may be coupled to the cover window WU to provide an accommodation space (e.g., a predetermined accommodation space). The display panel DP and the optical element ES may be accommodated in the accommodation space provided between the housing HM and the cover window WU.

The housing HM may include a material having a relatively high rigidity. For example, the housing HM may include glass, plastic, or metal, or a plurality of frames and/or plates made of a combination of the glass, the plastic, and the metal. The housing HM may stably protect components of the display device 1000 accommodated in an internal space from external impact.

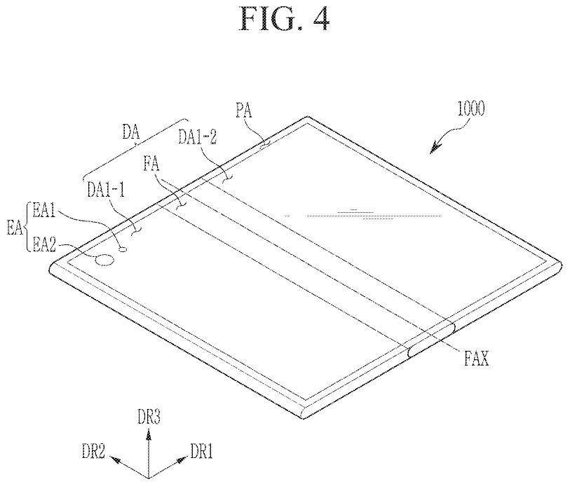

Hereinafter, a structure of the display device 1000 according to one or more other embodiments will be described with reference to FIG. 4. FIG. 4 is a perspective view schematically illustrating the display device according to one or more other embodiments. A description of the same components as those described above will be omitted.

In one or more embodiments of FIG. 4, a foldable display device having a structure in which the display device 1000 is folded through a folding axis (or a folding line) FAX is illustrated.

Referring to FIG. 4, in one or more embodiments, the display device 1000 may be the foldable display device. The display device 1000 may be folded outwardly or inwardly based on the folding axis FAX. When folded outwardly based on the folding axis FAX, display surfaces of the display device 1000 are respectively positioned outside in the third direction DR3 to display images in both directions. When folded inwardly based on the folding axis FAX, the display surfaces may not be visually recognized from the outside.

In one or more embodiments, the display device 1000 may include a display area DA, a component area EA, and a non-display area PA. The display area DA may be divided into a (1-1)-th display area DA1-1, a (1-2)-th display area DA1-2, and a folding area FA. The (1-1)-th display area DA1-1 and the (1-2)-th display area DA1-2 may be respectively positioned at left and right sides with respect to (or at a center of) the folding axis FAX. The folding area FA may be positioned between the (1-1)-th display area DA1-1 and the (1-2)-th display area DA1-2. In this case, when folded outwardly based on the folding axis FAX, the (1-1)-th display area DA1-1 and the (1-2)-th display area DA1-2 are positioned at both sides in the third direction DR3 so that images are displayed in both directions. In addition, when folded inwardly based on the folding axis FAX, the (1-1)-th display area DA1-1 and the (1-2)-th display area DA1-2 may not be visible from the outside.

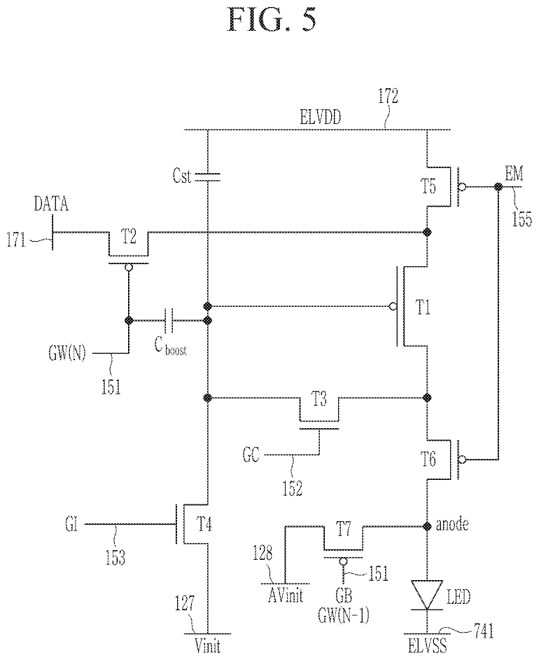

Hereinafter, a circuit structure of a pixel positioned at a lower panel layer of the display area DA will be described in detail with reference to FIG. 5. FIG. 5 is a circuit diagram of one pixel included in the display device according to one or more embodiments.

One pixel according to one or more embodiments includes a plurality of transistors T1, T2, T3, T4, T5, T6, and T7, a holding capacitor (or a storage capacitor) Cst, a boost capacitor C_{boost}, and a light-emitting diode LED that are connected to several wirings 127, 128, 151, 152, 153, 155, 171, 172, and 741. Here, transistors and capacitors except for the light-emitting diode LED constitute a pixel circuit. In one or more embodiments, the boost capacitor C_{boost} may be omitted.

The wirings 127, 128, 151, 152, 153, 155, 171, 172, and 741 are connected to one pixel PX. The wirings include a first initialization voltage line 127, a second initialization voltage line 128, a first scan line 151, a second scan line 152, an initialization control line 153, a light emission control line 155, a data line 171, a driving voltage line 172, and a common voltage line 741. The first scan line 151 connected to the seventh transistor T7 is also connected to the second transistor T2, but in one or more embodiments, the seventh transistor T7 may be connected to a separate bypass control line.

The first scan line 151 is connected to a scan driver to transmit a first scan signal GW(N) to the second transistor T2. A first scan line 151 at a previous stage transmits a previous-stage first scan signal GW(N−1) to the seventh transistor T7. A voltage having a polarity opposite to a voltage applied to the first scan line 151 may be applied to the second scan line 152 at the same timing as a signal of the first scan line 151. For example, when a negative voltage is applied to the first scan line 151, a positive voltage may be applied to the second scan line 152. The second scan line 152 transfers a second scan signal GC to the third transistor T3. The initialization control line 153 transfers an initialization control signal GI to the fourth transistor T4. The light emission control line 155 transfers a light emission control signal EM to the fifth transistor T5 and the sixth transistor T6.

The data line 171 is wiring that transmits a data voltage DATA generated by a data driver, and thus, a size of a light-emitting current transmitted to the light-emitting diode LED is changed so that luminance emitted by the light-emitting diode LED is also changed. The driving voltage line 172 applies a driving voltage ELVDD. The first initialization voltage line 127 transfers a first initialization voltage Vinit, and the second initialization voltage line 128 transfers a second initialization voltage AVinit. The common voltage line 741 applies a common voltage ELVSS to a cathode of the light-emitting diode LED. Each of voltages applied to the driving voltage line 172, the first and second initialization voltage lines 127 and 128, and the common voltage line 741 may be a constant voltage.

The driving transistor (also referred to as a first transistor) T1 is a p-type transistor and includes a silicon semiconductor as a semiconductor layer. The driving transistor T1 is a transistor that adjusts a magnitude of a light-emitting current output to an anode of the light-emitting diode LED according to a magnitude of a voltage (e.g., a voltage stored in the holding capacitor Cst) of a gate electrode of the driving transistor T1. Because a brightness of the light-emitting diode LED is adjusted according to a magnitude of a light-emitting current output to the anode electrode of the light-emitting diode LED, a light-emitting brightness of the light-emitting diode LED may be adjusted according to the data voltage DATA applied to the pixel. To this end, a first electrode of the driving transistor T1 is located to receive the driving voltage ELVDD, and is connected to the driving voltage line 172 via the fifth transistor T5. In addition, the first electrode of the driving transistor T1 is also connected to a second electrode of the second transistor T2 to receive the data voltage DATA. The second electrode of the driving transistor T1 outputs a light-emitting current to the light-emitting diode LED and is connected to the anode of the light-emitting diode LED via the sixth transistor (hereinafter also referred to as an output control transistor) T6. In addition, the second electrode of the driving transistor T1 is also connected to the third transistor T3 to transmit the data voltage DATA applied to the first electrode of the driving transistor T1 to the third transistor T3. The gate electrode of the driving transistor T1 is connected to one electrode (hereinafter referred to as a second holding electrode) of the holding capacitor Cst. Accordingly, a voltage of the gate electrode of the driving transistor T1 is changed according to the voltage stored in the holding capacitor Cst, and thus, a light-emitting current output from the driving transistor T1 is changed. The holding capacitor Cst serves to constantly maintain the voltage of the gate electrode of the driving transistor T1 for one frame time. The gate electrode of the driving transistor T1 may also be connected to the third transistor T3 so that the data voltage DATA applied to the first electrode of the driving transistor T1 passes through the third transistor T3 to be transmitted to the gate electrode of the driving transistor T1. The gate electrode of the driving transistor T1 may also be connected to the fourth transistor T4 to be initialized by receiving the first initialization voltage Vinit.

The second transistor T2 is a p-type transistor, and has a silicon semiconductor as a semiconductor layer. The second transistor T2 is a transistor that allows the data voltage DATA to be received into the pixel. A gate electrode of the second transistor T2 is connected to the first scan line 151 and one electrode (hereinafter referred to as a lower boost electrode) of the boost capacitor C_{boost}. A first electrode of the second transistor T2 is connected to the data line 171. A second electrode of the second transistor T2 is connected to the first electrode of the driving transistor T1. When the second transistor T2 is turned on by a negative voltage of the first scan signal GW transmitted through the first scan line 151, the data voltage DATA transmitted through the data line 171 is transmitted to the first electrode of the driving transistor T1, and finally, the data voltage DATA is transmitted to the gate electrode of the driving transistor T1, and is stored in the holding capacitor Cst.

The third transistor T3 is an n-type transistor, and has an oxide semiconductor as a semiconductor layer. The third transistor T3 electrically connects the second electrode of the driving transistor T1 and the gate electrode of the driving transistor T1. As a result, it is a transistor that allows the data voltage DATA to be compensated by a threshold voltage of the driving transistor T1 and to be then stored in the second holding electrode of the holding capacitor Cst. A gate electrode of the third transistor T3 is connected to the second scan line 152, and a first electrode of the third transistor T3 is connected to the second electrode of the driving transistor T1. A second electrode of the third transistor T3 is connected to the second holding electrode of the holding capacitor Cst, the gate electrode of the driving transistor T1, and the other electrode (hereinafter referred to as an upper boost electrode) of the boost capacitor C_{boost}. The third transistor T3 is turned on by a positive voltage of the second scan signal GC transmitted through the second scan line 152 to connect the gate electrode of the driving transistor T1 and the second electrode of the driving transistor T1, and to allow a voltage applied to the gate electrode of the driving transistor T1 to be transmitted to the second storage electrode of the holding capacitor Cst to be stored in the holding capacitor Cst. In this case, the voltage stored in the holding capacitor Cst is stored in a state in which the voltage of the gate electrode of the driving transistor T1 when the driving transistor T1 includes turned off is stored and a threshold voltage (Vth) of the driving transistor T1 is compensated.

The fourth transistor T4 is an n-type transistor, and has an oxide semiconductor as a semiconductor layer. The fourth transistor T4 serves to initialize the gate electrode of the driving transistor T1 and the second storage electrode of the holding capacitor Cst. A gate electrode of the fourth transistor T4 is connected to the initialization control line 153, and a first electrode of the fourth transistor T4 is connected to the first initialization voltage line 127. A second electrode of the fourth transistor T4 is connected to the second electrode of the third transistor T3, the second holding electrode of the holding capacitor Cst, the gate electrode of the driving transistor T1, and the upper boost electrode of the boost capacitor C_{boost}. The fourth transistor T4 is turned on by a positive voltage of the initialization control signal GI received through the initialization control line 153, and (at this time) transmits the first initialization voltage Vinit to the gate electrode of the driving transistor T1, the second holding electrode of the holding capacitor Cst, and the upper boost electrode of the boost capacitor C_{boost} to initialize them.

The fifth transistor T5 and the sixth transistor T6 are p-type transistors, and have a silicon semiconductor as a semiconductor layer.

The fifth transistor T5 serves to transmit the driving voltage ELVDD to the driving transistor T1. A gate electrode of the fifth transistor T5 is connected to the light emission control line 155, a first electrode of the fifth transistor T5 is connected to the driving voltage line 172, and a second electrode of the fifth transistor T5 is connected to the first electrode of the driving transistor T1.

The sixth transistor T6 serves to transmit a light-emitting current outputted from the driving transistor T1 to the light-emitting diode LED. A gate electrode of the sixth transistor T6 is connected to the light emission control line 155, a first electrode of the sixth transistor T6 is connected to the second electrode of the driving transistor T1, and a second electrode of the sixth transistor T6 is connected to the anode of the light-emitting diode LED.

The seventh transistor T7 is a p-type transistor or an n-type transistor, and has a silicon semiconductor or an oxide semiconductor as a semiconductor layer. The seventh transistor T7 serves to initialize the anode of the light-emitting diode LED. A gate electrode of the seventh transistor T7 is connected to the first scan line 151 at the previous stage, a first electrode of the seventh transistor T7 is connected to the anode of the light-emitting diode LED, and a second electrode of the seventh transistor T7 is connected to the second initialization voltage line 128. When the seventh transistor T7 is turned on by a negative voltage of the first scan line 151, the second initialization voltage AVinit is applied to the anode of the light-emitting diode LED to initialize it. The gate electrode of the seventh transistor T7 may also be connected to a separate bypass control line to be controlled by separate wiring other than the first scan line 151. In addition, in one or more embodiments, the second initialization voltage line 128 to which the second initialization voltage AVinit is applied may be the same as the first initialization voltage line 127 to which the first initialization voltage Vinit is applied.

It is described that one pixel PX includes the seven transistors T1 to T7 and two capacitors (the holding capacitor Cst and the boost capacitor C_{boost}), but the present disclosure is not limited thereto, and in one or more embodiments, the boost capacitor C_{boost} may be removed. In addition, although FIG. 5 shows that the third transistor T3 and the fourth transistor T4 are formed as n-type transistors, in one or more other embodiments, only one of the third transistor or the fourth transistor may be formed as an n-type transistor, or one or more other transistors (e.g., the seventh transistor and the like) may be formed as an n-type transistor.

As described above, a circuit structure of the pixel formed at the display area DA and the component area EA has been described with reference to FIG. 5.

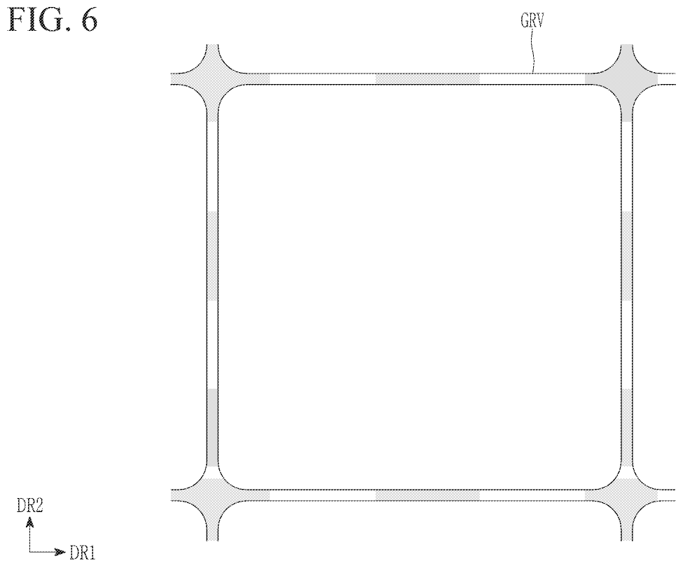

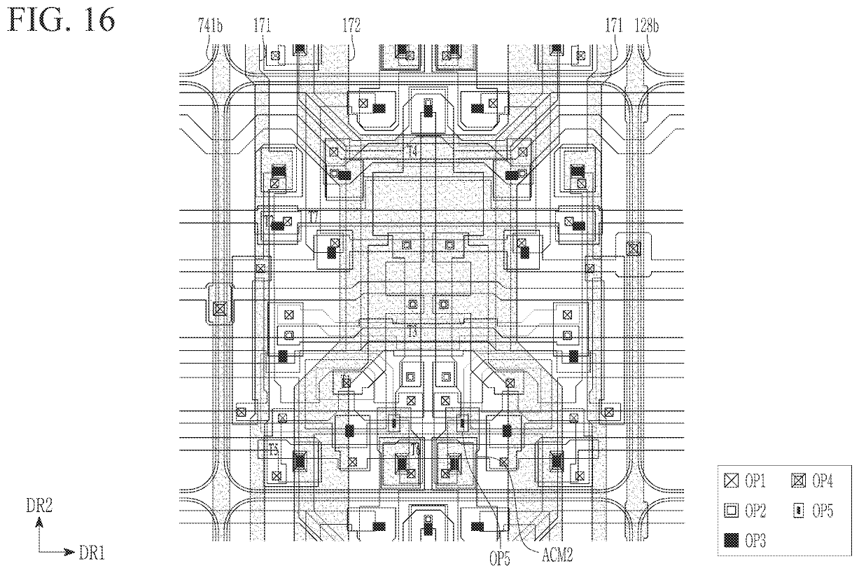

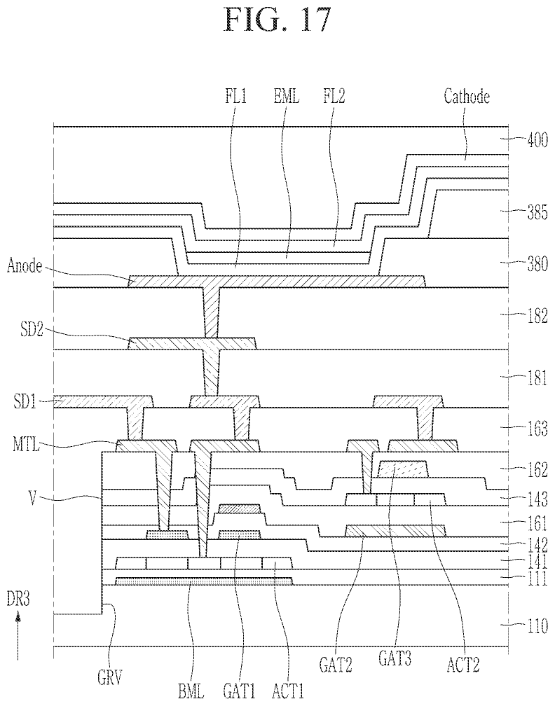

Hereinafter, the display panel according to one or more embodiments will be described with reference to FIGS. 6 to 17. FIGS. 6 to 16 are views illustrating in detail a structure of each layer according to a process of manufacturing a display panel layer of the display device according to one or more embodiments. FIG. 17 is a cross-sectional view of the display panel layer of FIG. 16.

First, referring to FIGS. 6 and 17, the display panel according to one or more embodiments includes a substrate 110. The substrate 110 may include a material (e.g., glass or the like) that does not bend due to a rigid characteristic, or a flexible material (e.g., plastic or polyimide) that may bend. A flexible substrate may have a two-layer structure in which polyimide, and a barrier layer formed of an inorganic insulating material formed on the polyimide, are repeatedly formed.

The substrate 110 according to one or more embodiments may include/define a groove GRV. The groove GRV may pass through the barrier layer included in the substrate, or may be formed in the barrier layer. The groove GRV may be formed to separate adjacent pixel circuit areas in the display area. For example, an area that is divided by a rectangular groove GRV on a plane may include two pixel circuit areas, and may be distinguished from other adjacent pixel circuit areas. However, the present disclosure is not limited thereto, and a shape of the groove GRV dividing the pixel circuit areas may be variously modified.

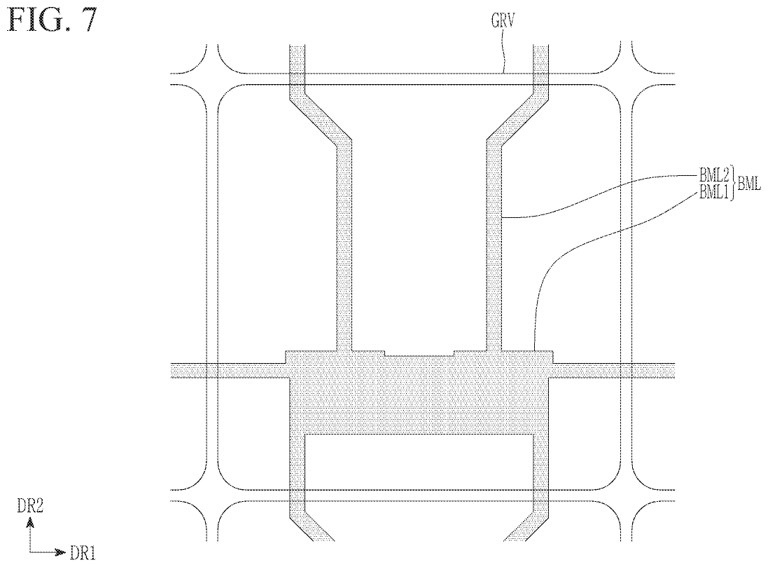

Next, referring to FIGS. 7 and 17, a metal layer BML is positioned on the substrate 110.

The metal layer BML includes a connection portion BML2, which may be for connecting an extension portion BML1 and an extension portion BML1 to each other. The extension portion BML1 of the metal layer BML may be formed at a position that overlaps a channel 1132 of the driving transistor T1 of a subsequent first semiconductor layer on a plane.

The metal layer BML is also referred to as a lower shielding layer, may include a metal, such as copper (Cu), molybdenum (Mo), aluminum (Al), titanium (Ti), or the like, or a metal alloy, may further include amorphous silicon, and may include a single layer or multiple layers.

Referring to FIG. 17, a buffer layer 111 covering the substrate 110 and the metal layer BML is located on the substrate 110 and the metal layer BML. The buffer layer 111 serves to block penetration of an impurity element into the first semiconductor layer 130, and may be an inorganic insulating film including a silicon oxide (SiOx), a silicon nitride (SiNx), a silicon oxynitride (SiOxNy), or the like.

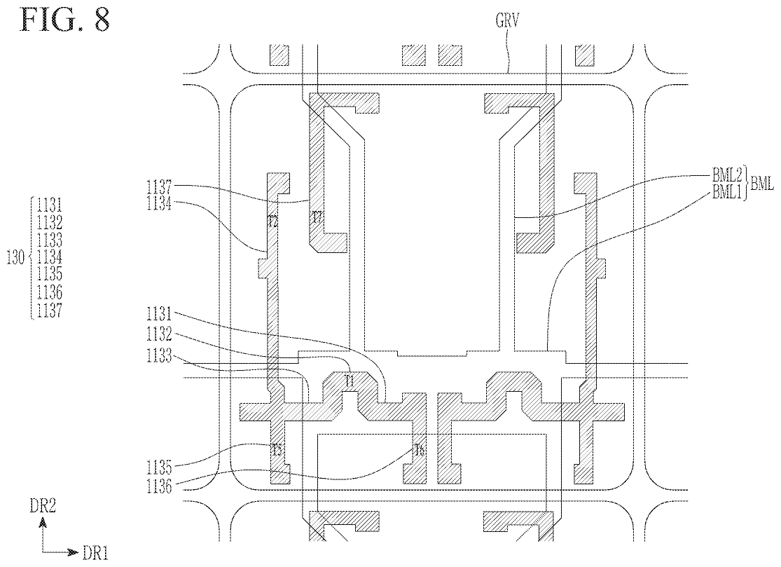

Next, referring to FIG. 8, the first semiconductor layer 130 formed of a silicon semiconductor (e.g., a polycrystalline semiconductor) is positioned above or on the buffer layer 111. The first semiconductor layer 130 includes the channel 1132, a first region 1131, and a second region 1133 of the driving transistor T1. In addition, the first semiconductor layer 130 includes a channel of the second transistor T2, a channel of the fifth transistor T5, a channel of the sixth transistor T6, and a channel of the seventh transistor T7 as well as the channel of the driving transistor T1. A region having a conductive layer characteristic is provided on both sides of the channel by plasma treatment or doping so that the region serves as the first electrode or the second electrode.

The channel 1132 of the driving transistor T1 may have a curved shape on a plane. However, a shape of the channel 1132 of the driving transistor T1 is not limited thereto, and may be variously changed. For example, the channel 1132 of the driving transistor T1 may be bent in another shape or may have a bar shape. The first region 1131 and the second region 1133 of the driving transistor T1 may be positioned at both sides of the channel 1132 of the driving transistor T1. The first region 1131 and the second region 1133 positioned in the first semiconductor layer serve as the first electrode and the second electrode of the driving transistor T1.

In the first semiconductor layer 130, the channel, a first region, and a second region of the second transistor T2 are positioned at a portion 1134 extending upward from the second region 1133 of the driving transistor T1 in the second direction DR2. The channel, a first region, and a second region of the fifth transistor T5 are positioned at a portion 1135 extending downward in the second direction DR2 from the second region 1133 of the driving transistor T1. The channel, a first region, and a second region of the sixth transistor T6 are positioned at a portion 1136 extending downward in the second direction DR2 from the first region 1131 of the driving transistor T1. The first semiconductor layer 130 includes a portion 1137 positioned adjacent to the channel, the first region, and the second region of the second transistor T2, and the portion 1137 includes the channel, a first region, and a second region of the seventh transistor T7.

Referring to FIG. 17, a first gate-insulating film 141 may be positioned on the first semiconductor layer ACT1. The first gate-insulating film 141 may be a single-layer inorganic insulating film or multi-layer inorganic insulating films including a silicon oxide (SiOx), a silicon nitride (SiNx), a silicon oxynitride (SiOxNy), or the like.

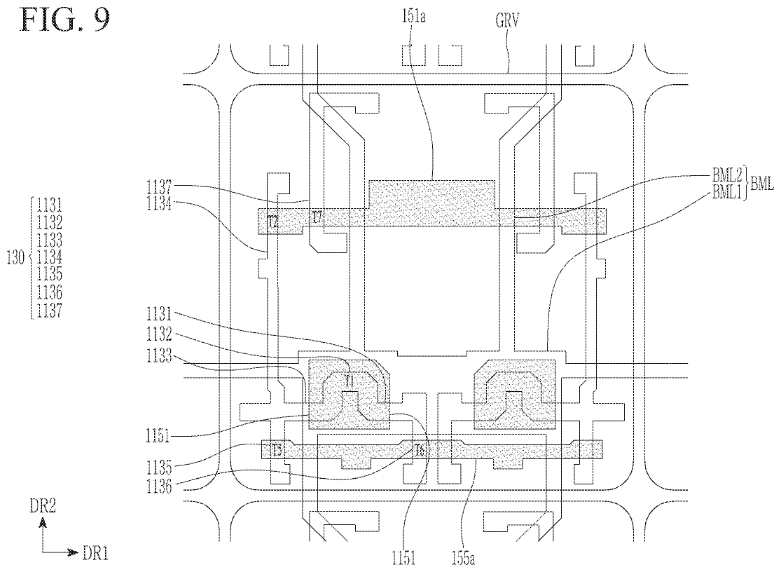

Next, referring to FIG. 9, a first gate conductive layer including the gate electrode 1151 of the driving transistor T1 may be positioned above or on the first gate-insulating film 141. The first gate conductive layer includes the gate electrode of the second transistor T2, the gate electrode of the fifth transistor T5, the gate electrode of the sixth transistor T6, and the gate electrode of the seventh transistor T7, as well as the gate electrode of the driving transistor T1. The gate electrode 1151 of the driving transistor T1 may overlap the channel 1132 of the driving transistor T1. The channel 1132 of the driving transistor T1 is covered by the gate electrode 1151 of the driving transistor T1.

The first gate conductive layer may further include a lower first scan line 151a and a lower light emission control line 155a. The lower first scan line 151a and the lower light emission control line 155a may extend substantially in a horizontal direction (hereinafter also referred to as the first direction DR1). The lower first scan line 151a may be connected to the gate electrode of the second transistor T2. The lower first scan line 151a may be formed integrally with the gate electrode of the second transistor T2. The lower first scan line 151a may also be connected to the gate electrode of the seventh transistor T7 of a previous stage pixel. The lower first scan line 151a may be formed integrally with the gate electrode of the seventh transistor T7.

The lower light emission control line 155a may be connected to the gate electrode of the fifth transistor T5 and/or the gate electrode of the sixth transistor T6. The lower light emission control line 155a, the gate electrode of the fifth transistor T5, and the gate electrode of the sixth transistor T6 may be integrally formed.

The first gate conductive layer may include a metal, such as copper (Cu), molybdenum (Mo), aluminum (Al), titanium (Ti), or the like, or a metal alloy, and may include a single layer or multiple layers.

After the first gate conductive layer including the gate electrode 1151 of the driving transistor T1 is formed, an exposed area of the first semiconductor layer may be made conductive by performing a plasma treatment or a doping process. That is, the first semiconductor layer covered by the first gate conductive layer may not be conductive, and a portion of the first semiconductor layer not covered by the first gate conductive layer may have the same characteristic as that of a conductive layer. As a result, a transistor including a conductive portion may have a p-type transistor characteristic so that the driving transistor T1, the second transistor T2, the fifth transistor T5, the sixth transistor T6, and the seventh transistor T7 are p-type transistors.

Referring to FIG. 17, a second gate-insulating film 142 may be positioned on the first gate-insulating film 141 and the first gate conductive layer GAT1 including the gate electrode 1151 of the driving transistor T1. The first gate-insulating film 141 may be a single-layer inorganic insulating film or multi-layer inorganic insulating films including a silicon oxide (SiOx), a silicon nitride (SiNx), a silicon oxynitride (SiOxNy), or the like.

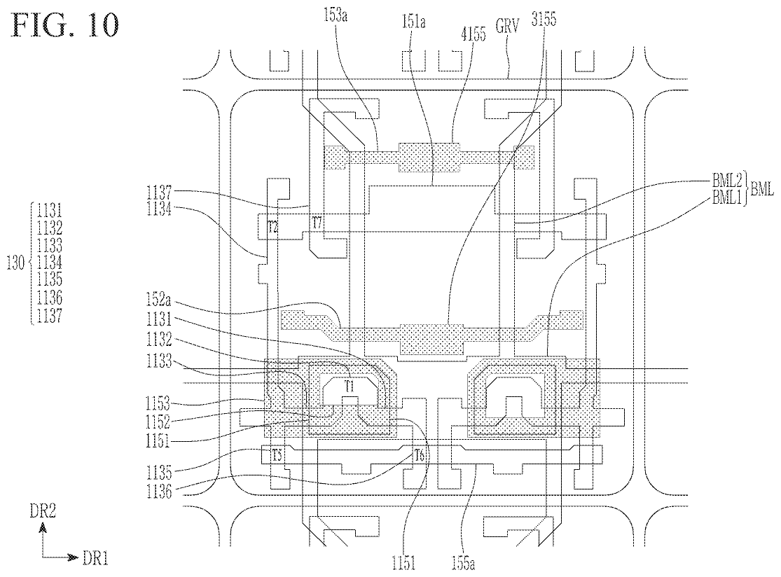

Next, referring to FIG. 10, a second gate conductive layer including a first holding electrode 1153 of the holding capacitor Cst, a lower shielding layer 3155 of the third transistor T3, and a lower shielding layer 4155 of the fourth transistor T4 may be positioned above or on the second gate-insulating film 142. The lower shielding layers 3155 and 4155 may be respectively positioned below channels of the third transistor T3 and the fourth transistor T4 so that the lower shielding layers serve to shield the channels from light, electromagnetic interference, or the like provided from a lower side.

The first holding electrode 1153 overlaps the gate electrode 1151 of the driving transistor T1 to form the holding capacitor Cst. An opening 1152 is formed at the first holding electrode 1153 of the holding capacitor Cst. The opening 1152 of the first holding electrode 1153 of the holding capacitor Cst may overlap the gate electrode 1151 of the driving transistor T1.

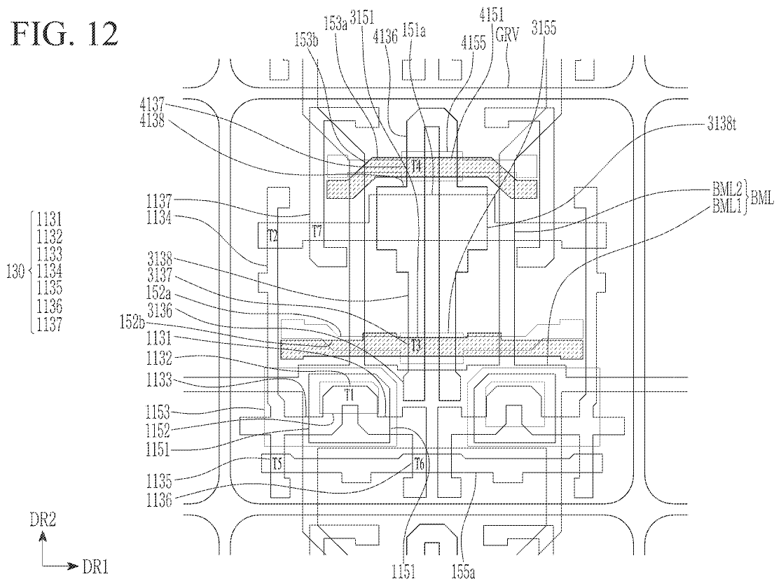

The lower shielding layer 3155 of the third transistor T3 may overlap a channel 3137 and the gate electrode 3151 of the third transistor T3 to be described later. The lower shielding layer 4155 of the fourth transistor T4 may overlap a channel 4137 (e.g., see FIG. 12) and the gate electrode 4151 (e.g., see FIG. 12) of the fourth transistor T4 to be described later.

The second gate conductive layer may further include a lower second scan line 152a and a lower initialization control line 153a. The lower second scan line 152a and the lower initialization control line 153a may extend substantially in the horizontal direction (the first direction). The lower second scan line 152a may be connected to the lower shielding layer 3155 of the third transistor T3. The lower second scan line 152a may be formed integrally with the lower shielding layer 3155 of the third transistor T3. The lower initialization control line 153a may be connected to the lower shielding layer 4155 of the fourth transistor T4. The lower initialization control line 153a may be formed integrally with the lower shielding layer 4155 of the fourth transistor T4.

Second gate conductive layers positioned at adjacent pixel circuit areas may be spaced apart from each other. The second gate conductive layer GAT2 may include a metal, such as copper (Cu), molybdenum (Mo), aluminum (Al), titanium (Ti), or the like, or a metal alloy, and may include a single layer or multiple layers.

Referring to FIG. 17, a first interlayer insulating film 161 including the first holding electrode 1153 of the holding capacitor Cst, the lower shielding layer 3155 of the third transistor T3, and the lower shielding layer 4155 of the fourth transistor T4 may be positioned on the second gate conductive layer GAT2.

The first interlayer insulating film 161 may include a single-layer inorganic insulating film or multi-layer inorganic insulating films including a silicon oxide (SiOx), a silicon nitride (SiNx), a silicon oxynitride (SiOxNy), or the like, and according to one or more embodiments, an inorganic insulating material may be thickly formed.

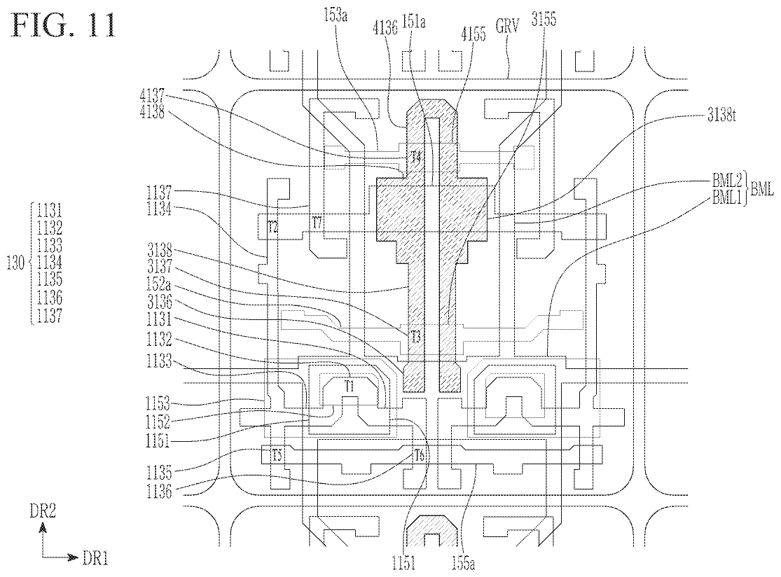

Next, referring to FIGS. 11 and 17, a second semiconductor layer including the channel 3137, a first region 3136, and a second region 3138 of the third transistor T3, and the channel 4137, a first region 4136, and a second region 4138 of the fourth transistor T4, may be positioned above or on the first interlayer insulating film 161. The second semiconductor layer may include an oxide semiconductor. The second semiconductor layer may include the upper boost electrode 3138t of the capacitor C_{boost}.

The channel 3137, the first region 3136, and the second region 3138 of the third transistor T3, and the channel 4137, the first region 4136, and the second region 4138 of the fourth transistor T4, may be connected to each other to be formed integrally. The first region 3136 and the second region 3138 of the third transistor T3 are positioned on respective sides of the channel 3137 of the third transistor T3, and the first region 4136 and the second region 4138 of the fourth transistor T4 are positioned on respective sides of the channel 4137 of the fourth transistor T4. The second region 3138 of the third transistor T3 is connected to the second region 4138 of the fourth transistor T4. The channel 3137 of the third transistor T3 overlaps the lower shielding layer 3155, and the channel 4137 of the fourth transistor T4 overlaps the lower shielding layer 4155.

The upper boost electrode 3138t of the capacitor C_{boost} is positioned between the second region 3138 of the third transistor T3 and the second region 4138 of the fourth transistor T4. The upper boost electrode 3138t of the boost capacitor C_{boost} overlaps an extended portion of the lower first scan line 151a of the boost capacitor C_{boost} to form the boost capacitor C_{boost}.

Second semiconductor layers positioned at adjacent pixel circuit areas may be spaced apart from each other.

Referring to FIG. 17, the second semiconductor layer ACT2 including the channel 3137, the first region 3136, and the second region 3138 of the third transistor T3, the channel 4137, the first region 4136, and the second region 4138 of the fourth transistor T4, and the upper boost electrode 3138t of the boost capacitor C_{boost} may be positioned on a third gate-insulating film 143.

The third gate-insulating film 143 may be positioned on a front surface of the second semiconductor layer ACT2 and the first interlayer insulating film 161. Accordingly, the third gate-insulating film 143 may cover upper surfaces and side surfaces of the channel 3137, the first region 3136, and the second region 3138 of the third transistor T3, the channel 4137, the first region 4136, and the second region 4138 of the fourth transistor T4, and the upper boost electrode 3138t of the boost capacitor C_{boost}. However, the present disclosure is not limited thereto, and the third gate-insulating film 143 might not be positioned on the front surface of the second semiconductor layer ACT2 and the first interlayer insulating film 161. For example, the third gate-insulating film 143 may overlap the channel 3137 of the third transistor T3 while not overlapping the first region 3136 and the second region 3138. In addition, the third gate-insulating film 143 may overlap the channel 4137 of the fourth transistor T4 while not overlapping the first region 4136 and the second region 4138.

The third gate-insulating film 143 may include a single-layer inorganic insulating film or multi-layer inorganic insulating films including a silicon oxide (SiOx), a silicon nitride (SiNx), a silicon oxynitride (SiOxNy), or the like

Referring to FIG. 12, a third gate conductive layer including the gate electrode 3151 of the third transistor T3 and the gate electrode 4151 of the fourth transistor T4 may be positioned above or on the third gate-insulating film 143.

The gate electrode 3151 of the third transistor T3 may overlap the channel 3137 of the third transistor T3. The gate electrode 3151 of the third transistor T3 may overlap the lower shielding layer 3155 of the third transistor T3.

The gate electrode 4151 of the fourth transistor T4 may overlap the channel 4137 of the fourth transistor T4. The gate electrode 4151 of the fourth transistor T4 may overlap the lower shielding layer 4155 of the fourth transistor T4.

The third gate conductive layer may further include an upper second scan line 152b and an upper initialization control line 153b.

The upper second scan line 152b and the upper initialization control line 153b may extend substantially in the horizontal direction (the first direction DR1). The upper second scan line 152b may form the second scan line 152 together with the lower second scan line 152a. The upper second scan line 152b may be connected to the gate electrode 3151 of the third transistor T3. The upper second scan line 152b may be formed integrally with the gate electrode 3151 of the third transistor T3. The upper initialization control line 153b may form the initialization control line 153 together with the lower initialization control line 153a. The upper initialization control line 153b may be connected to the gate electrode 4151 of the fourth transistor T4. The upper initialization control line 153b may be formed integrally with the gate electrode 4151 of the fourth transistor T4.

Third gate conductive layers positioned at adjacent pixel circuit areas may be spaced apart from each other.

The third gate conductive layer GAT3 may include a metal, such as copper (Cu), molybdenum (Mo), aluminum (Al), titanium (Ti), or the like, or a metal alloy, and may be configured as a single layer or multiple layers.

After the third gate conductive layer including the gate electrode 3151 of the third transistor T3 and the gate electrode 4151 of the fourth transistor T4 is formed, through a plasma treatment or a doping process, a portion of an oxide semiconductor layer covered by the third gate conductive layer is formed as a channel, and a portion of an oxide semiconductor layer not covered by the third gate conductive layer is conductive. The channel 3137 of the third transistor T3 may be positioned below the gate electrode 3151 to overlap the gate electrode 3151. The first region 3136 and the second region 3138 of the third transistor T3 may not overlap the gate electrode 3151. The channel 4137 of the fourth transistor T4 may be positioned below the gate electrode 4151 to overlap the gate electrode 4151. The first region 4136 and the second region 4138 of the fourth transistor T4 may not overlap the gate electrode 4151. The upper boost electrode 3138t may not overlap the third gate conductive layer. A transistor including the oxide semiconductor layer may have a characteristic of an n-type transistor.

Referring back to FIG. 17, a second interlayer insulating film 162 may be positioned on the third gate conductive layer GAT3 including the gate electrode 3151 of the third transistor T3 and the gate electrode 4151 of the fourth transistor T4.

The second interlayer insulating film 162 may have a single-layer or multi-layer structure. The second interlayer insulating film 162 may include an inorganic insulating material, such as a silicon nitride (SiNx), a silicon oxide (SiOx), a silicon oxynitride (SiOxNy), or the like, and may include an organic material in one or more embodiments.

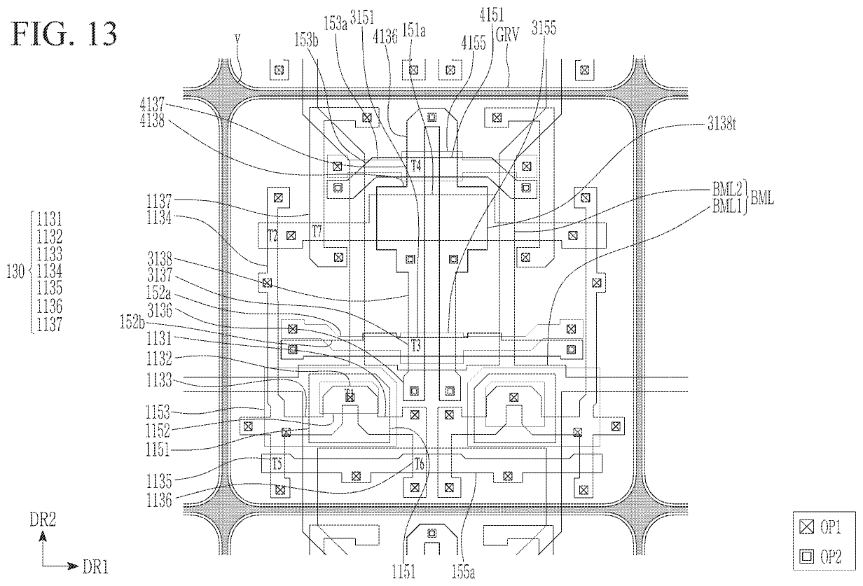

Next, referring to FIGS. 13 and 17, a valley V penetrating the second interlayer insulating film 162, the third gate-insulating film 143, the first interlayer insulating film 161, the second gate-insulating film 142, and the first gate-insulating film 141 may be formed. The valley V may separate adjacent pixel circuit areas. The present specification has shown one or more embodiments penetrating up to the barrier layer of the substrate 110, but the present disclosure is not limited thereto, and one or more embodiments penetrating up to the first gate-insulating film 141 or the buffer layer 111 may be possible. A shape of the valley V dividing the pixel circuit areas may be variously modified.

Two types of openings OP1 and OP2 may be formed at the second interlayer insulating film 162. The two types of openings OP1 and OP2 may be formed using different masks.

The first opening OP1 may be an opening formed at least one of the second interlayer insulating film 162, the third gate-insulating film 143, the first interlayer insulating film 161, the second gate-insulating film 142, and the first gate-insulating film 141, and may expose the first semiconductor layer 130, the first gate conductive layer, or the second gate conductive layer.

The second opening OP2 may be an opening formed at the second interlayer insulating film 162 and/or the third gate-insulating film 143, and may expose the oxide semiconductor layer or the third gate conductive layer.

One of first openings OP1 may overlap at least a portion of the gate electrode 1151 of the driving transistor T1, and may also be formed at the third gate-insulating film 143, the first interlayer insulating film 161, and the second gate-insulating film 142. In this case, one of the first openings OP1 may overlap the opening 1152 of the first holding electrode 1153, and may be positioned inside the opening 1152 of the first holding electrode 1153.

One of second openings OP2 may at least partially overlap the boost capacitor C_{boost}, and may be formed at the third gate-insulating film 143. The other one of the second openings OP2 may overlap at least a portion of the first region 3136 of the third transistor T3, and may be formed at the third gate-insulating film 143.

According to one or more embodiments, the valley V may be formed in a process of forming the first opening OP1 or the second opening OP2.

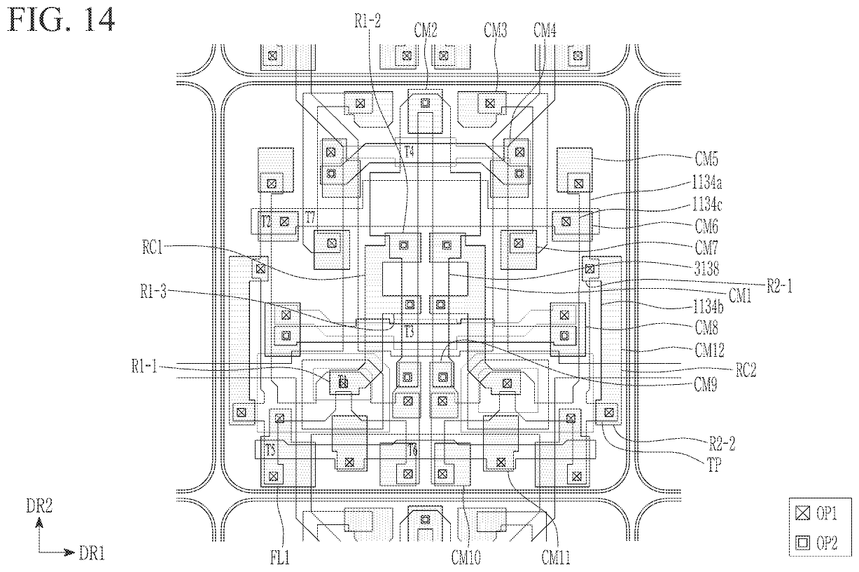

Then, referring to FIGS. 14 and 17, a connection metal conductive layer MTL including a plurality of connection electrodes may be positioned on the second interlayer insulating film 162. The connection metal conductive layer MTL may include first to twelfth connection electrodes CM1, CM2, CM3, CM4, CM5, CM6, CM7, CMB, CM9, CM10, CM11, and CM12, and a first connection part FL1.

The connection metal conductive layer MTL may include a metal having excellent flexibility, and for example, may include at least one of gold (Au), silver (Ag), aluminum (Al), copper (Cu), platinum (Pt), and iron (Fe).

The first connection electrode CM1 may overlap the gate electrode 1151 of the driving transistor T1. The first connection electrode CM1 may be connected to the gate electrode 1151 of the driving transistor T1 through the first opening OP1 and the opening 1152 of the first holding electrode 1153. The first connection electrode CM1 may overlap the boost capacitor C_{boost}. The first connection electrode CM1 may be connected to the upper boost electrode 3138t of the boost capacitor C_{boost} through the second opening OP2. Accordingly, the gate electrode 1151 of the driving transistor T1 and the upper boost electrode 3138t of the boost capacitor C_{boost} may be connected by the first connection electrode CM1. In this case, the gate electrode 1151 of the driving transistor T1 may be connected to the second region 3138 of the third transistor T3 and the second region 4138 of the fourth transistor T4 by the first connection electrode CM1.

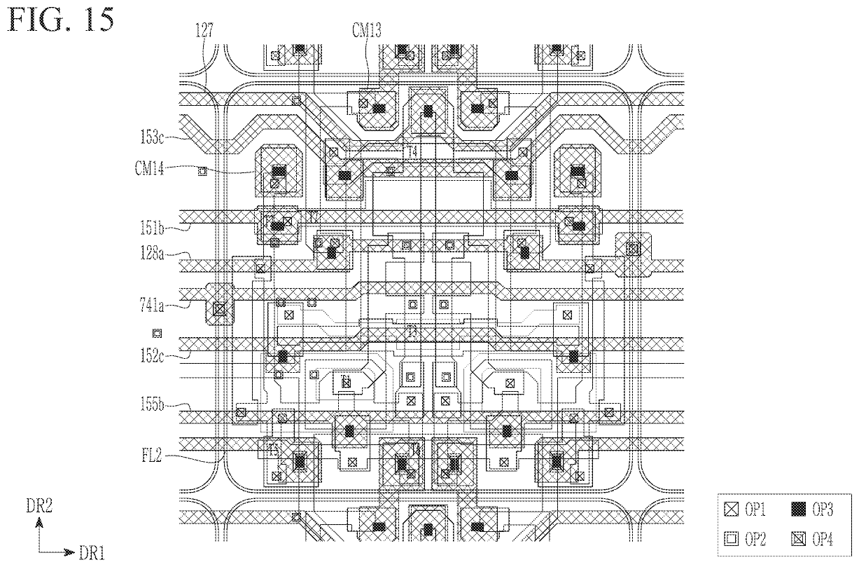

The second connection electrode CM2 may connect the first initialization voltage line 127 to be described later to the fourth transistor T4. The third connection electrode CM3 may be connected to the seventh transistor T7. In addition, the tenth connection electrode CM10 may be connected to the sixth transistor T6. The third connection electrode CM3 and the tenth connection electrode CM10 may be connected through a thirteenth connection electrode CM13 (e.g., see FIG. 15) to be described later. That is, the sixth transistor T6 and the seventh transistor T7 may be connected through the third connection electrode CM3, the tenth connection electrode CM10, and the thirteenth connection electrode CM13. The fourth connection electrode CM4 may connect the upper initialization control line 153b and the lower initialization control line 153a. The fifth connection electrode CM5 may electrically connect the second transistor T2 and the data line 171 to be described later. The sixth connection electrode CM6 may connect an upper first scan line 151b and the lower first scan line 151a. The seventh connection electrode CM7 may electrically connect the seventh transistor T7 and the second initialization voltage line 128. The eighth connection electrode CM8 may electrically connect the lower second scan line 152a, the upper second scan line 152b, and a connection second scan line 152c. The ninth connection electrode CM9 may connect the third transistor T3 and the first transistor T1. The eleventh connection electrode CM11 may connect the lower light emission control line 155a and an upper light emission control line 155b. The twelfth connection electrode CM12 may electrically connect the second transistor T2 and the first transistor T1. The first connection part FL1 may electrically connect the fifth transistor T5 and the first holding electrode 1153 through the first opening OP1.

Hereinafter, the first connection electrode CM1 and the twelfth connection electrode CM12 will be described in more detail.

The first connection electrode CM1 may include a (1-1)-th region R1-1 connected to the gate electrode 1151 of the first transistor T1 and a (1-2)-th region R1-2 connected to the third transistor T3. The (1-1)-th region R1-1 may be electrically connected to the gate electrode 1151 of the first transistor T1 through the first opening OP1. The (1-2)-th region R1-2 may be connected to the second region 3138 of the third transistor T3 and/or the second region 4138 of the fourth transistor T4 through the second opening OP2. Alternatively, the (1-2)-th region R1-2 may be connected to the upper boost electrode 3138t of the boost capacitor C_{boost} through the second opening OP2.

The first connection electrode CM1 may include a first connection region RC1 connecting the (1-1)-th region R1-1 and the (1-2)-th region R1-2. The first connection region RC1 may have a shape extending substantially in the second direction DR2, but is not limited thereto, and may have any shape for connecting the (1-1)-th region R1-1 and the (1-2)-th region R1-2.

The first connection electrode CM1 may include a (1-3)-th region R1-3 protruding from the first connection region RC1. The (1-3)-th region R1-3 may have a shape that protrudes substantially along the first direction DR1. The (1-3)-th region R1-3 may overlap the second region 3138 of the third transistor T3. The (1-3)-th region R1-3 may be electrically connected to the second region 3138 of the third transistor T3 through the second opening OP2.

The (1-3)-th region R1-3 may have any shape for being connected to the second region 3138 of the third transistor T3, and, for example, may overlap the second region 3138 of the third transistor T3 at a position that does not overlap the second gate conductive layer and the third gate conductive layer. The (1-3)-th region R1-3 may be spaced apart from the second gate conductive layer and the third gate conductive layer on a plane. In detail, the (1-3)-th region R1-3 may be spaced apart from the gate electrode 3151 of the third transistor T3 and the lower shielding layer 3155 of the third transistor T3 on a plane.

Each of the (1-2)-th region R1-2 and the (1-3)-th region R1-3 may protrude from the first connection region RC1. Each of the (1-2)-th region R1-2 and the (1-3)-th region R1-3 may be electrically connected to the third transistor T3 through the second opening OP2. The (1-2)-th region R1-2 and the (1-3)-th region R1-3 may be spaced apart from each other in the second direction DR2 on a plane. There may be a space between the (1-2)-th region R1-2 and the (1-3)-th region R1-3. Even if a micro-crack is generated in the third transistor T3 in the space between the (1-2)-th region R1-2 and the (1-3)-th region R1-3, a connection of the third transistor T3 may be maintained through the (1-2)-th region R1-2 and the (1-3)-th region R1-3.

The second region 3138 of the third transistor T3 extending along the second direction DR2 may be vulnerable to a corresponding test (e.g., evaluation of stiffness against pen drop or the like) of the display device. In the second region 3138, a micro-crack may be generated during a corresponding inspection, when the display device is bent, or the like. In the display device according to one or more embodiments, each of the (1-2)-th region R1-2 and the (1-3)-th region R1-3 of the first connection electrode CM1 may be connected to the second region 3138 of the third transistor T3. Even if a portion of a path of the third transistor T3 is cut off, an electrical connection state may still be maintained through the (1-2)-th region R1-2 and the (1-3)-th region R1-3 of the first connection electrode CM1.

The twelfth connection electrode CM12 may have a bar shape extending substantially along the second direction DR2. The twelfth connection electrode CM12 may overlap the second transistor T2. For example, the second transistor T2 includes a first region 1134a electrically connected to the data line 171, a second region 1134b electrically connected to the first transistor T1, and a channel 1134c positioned between the first region 1134a and the second region 1134b. The channel 1134c may overlap the first scan line 151.

The twelfth connection electrode CM12 may include a (2-1)-th region R2-1, a (2-2)-th region R2-2, and a second connection region RC2. Each of the (2-1)-th region R2-1 and the (2-2)-th region R2-2 may overlap the second region 1134b of the second transistor T2. Each of the (2-1)-th region R2-1 and the (2-2)-th region R2-2 may be connected to the second region 1134b of the second transistor T2 through the first opening OP1. The second connection region RC2 may extend substantially in the second direction DR2 and may not overlap the second transistor T2 according to one or more embodiments. The second connection region RC2 may be spaced apart from the second transistor T2 on a plane.

The second transistor T2 overlapping the twelfth connection electrode CM12 may have a protrusion TP protruding along the first direction DR1. A portion of the second transistor T2 overlapping the (2-1)-th region R2-1 and a portion of the second transistor T2 overlapping the (2-2)-th region R2-2 may have a shape protruding along the first direction DR1. The second transistor T2 may overlap the first opening OP1 in the protrusion TP, and may be connected to the twelfth connection electrode CM12 through the first opening OP1.

The second region 1134b of the second transistor T2 extending along the second direction DR2 may be vulnerable to a corresponding test (e.g., evaluation of stiffness against pen drop or the like) of the display device. A micro-crack may be generated in the second region 1134b during a corresponding inspection, when the display device is bent, or the like. In the display device according to one or more embodiments, each of the (2-1)-th region R2-1 and the (2-2)-th region R2-2 of the twelfth connection electrode CM12 may be connected to the second region 1134b of the second transistor T2. Even if a portion of a path of the second transistor T2 is cut off, an electrical connection state may still be maintained through the (2-1)-th region R2-1 and the (2-2)-th region R2-2 of the twelfth connection electrode CM12.

When the second transistor T2 positioned in the first semiconductor layer is cut off or the third transistor T3 positioned in the second semiconductor layer is cut off, a problem in which a corresponding pixel is displayed as a bright spot may occur. According to one or more embodiments, even if a disconnection occurs due to a crack in the first semiconductor layer or the second semiconductor layer, an electrical connection through a metal connection electrode positioned at a different layer from the first semiconductor layer or the second semiconductor layer is maintained so that the likelihood of a corresponding pixel being displayed due to a defective bright spot may be reduced or prevented, and the display device having improved reliability is provided.

Next, referring to FIG. 17, a third interlayer insulating film 163 may be positioned on the connection metal conductive layer MTL. The third interlayer insulating film 163 may be formed to fill the valley V. The plurality of pixel circuit areas may be divided by the third interlayer insulating film 163. The first semiconductor layer, the second semiconductor layer, and the first to third gate conductive layers positioned in different pixel circuit areas are not directly connected to each other, and are spaced apart by the third interlayer insulating film 163.

The third interlayer insulating film 163 may be positioned between the plurality of pixel circuit areas and may be formed to surround an edge of the pixel circuit area. The valley V may be formed at portions of the second interlayer insulating film 162, the first interlayer insulating film 161, the third gate-insulating film 143, the second gate-insulating film 142, the first gate-insulating film 141, the buffer layer 111, and the substrate 110 that are made of an inorganic material and the third interlayer insulating film 163 made of an organic material may be positioned in the valley V so that each pixel circuit area is formed as an island type. Accordingly, even if an external impact is applied to portions of the second interlayer insulating film 162, the first interlayer insulating film 161, the third gate-insulating film 143, the second gate-insulating film 142, the first gate-insulating film 141, the buffer layer 111, and the substrate 110, an effect on adjacent other pixels may be reduced or prevented because the pixel circuit areas have independent structures by the third interlayer insulating film 163 made of the organic material. That is, it is possible to reduce or prevent the likelihood of a crack generated in one region from propagating in a horizontal direction.

The third interlayer insulating film 163 may include an organic material, a non-conductive inorganic material, a metal, or the like.

Next, referring to FIGS. 15 and 17, after a third opening OP3 is formed at the third interlayer insulating film 163, a first data conductive layer SD1 may be formed. A first organic layer 181 may be formed on the first data conductive layer, and a fourth opening OP4 may be formed at the first organic layer 181.

The first data conductive layer SD1 may include the first initialization voltage line 127, a connection initialization control line 153c, the thirteenth connection electrode CM13, a fourteenth connection electrode CM14, the upper first scan line 151b, a lower second initialization voltage line 128a, a lower common voltage line 741a, the connection second scan line 152c, the upper light emission control line 155b, and a second connection part FL2.

The first initialization voltage line 127 may be connected to the fourth transistor T4 through the third opening OP3. The connection initialization control line 153c may be connected to the lower initialization control line 153a and the upper initialization control line 153b. The connection initialization control line 153c, the lower initialization control line 153a, and the upper initialization control line 153b may form the initialization control line 153. The fourteenth connection electrode CM14 may electrically connect the second transistor T2 and the data line 171. The upper first scan line 151b may be connected to the lower first scan line 151a through the third opening OP3. The lower second initialization voltage line 128a may be connected to an upper second initialization voltage line 128b to be described later, and may be connected to the seventh transistor T7 through the seventh connection electrode CM7.

The lower common voltage line 741a may be connected to an upper common voltage line 741b (e.g., see FIG. 16) through the fourth opening OP4. The connection second scan line 152c may be connected to the upper second scan line 152b and the lower second scan line 152a through the third opening OP3. The connection second scan line 152c, the upper second scan line 152b, and the lower second scan line 152a may form the second scan line 152. The upper light emission control line 155b may be connected to the lower light emission control line 155a through the third opening OP3. The upper light emission control line 155b and the lower light emission control line 155a may form the light emission control line 155. The second connection part FL2 may be electrically connected to the first connection part FL1 through the third opening OP3.

Next, referring to FIGS. 16 and 17, a second data conductive layer SD2 including the upper second initialization voltage line 128b, the data line 171, the driving voltage line 172, the upper common voltage line 741b, and an anode connection member ACM2 may be positioned on the first organic layer 181. The upper second initialization voltage line 128b, the data line 171, the driving voltage line 172, and the upper common voltage line 741b may be positioned at the plurality of pixel circuit areas.

The upper second initialization voltage line 128b, the data line 171, the driving voltage line 172, and the upper common voltage line 741b may extend substantially in a longitudinal direction (the second direction DR2).

The upper second initialization voltage line 128b is connected to the lower second initialization voltage line 128a through the fourth opening OP4. The upper second initialization voltage line 128b may overlap the valley V dividing the pixel circuit areas and the third interlayer insulating film 163.

The data line 171 is connected to the fourteenth connection electrode CM14 of the first data conductive layer through the fourth opening OP4, and thus is electrically connected to the second transistor T2.

The driving voltage line 172 may be electrically connected to the second connection part FL2 of the first data conductive layer through the fourth opening OP4. The second connection part FL2 may be electrically connected to the first connection part FL1 through the third opening OP3. The first connection part FL1 is electrically connected to the fifth transistor T5 and the first holding electrode 1153 through the first opening OP1. The driving voltage line 172 may transmit a driving voltage to the fifth transistor T5 and the first holding electrode 1153.

The anode connection member ACM2 is electrically connected to the sixth transistor T6, and may be connected to the anode through the fifth opening OP5.

The second data conductive layer SD2 may include a metal, such as aluminum (Al), copper (Cu), molybdenum (Mo), titanium (Ti), or the like, or a metal alloy, and may be configured as a single layer or multiple layers.

Next, referring to FIG. 17, a second organic film 182 is positioned on the second data conductive layer SD2. The anode is positioned on the second organic film 182. The anode may receive a current from the pixel circuit through an anode connection opening OP5. The anode according to one or more embodiments may be electrically connected to the sixth transistor T6.

A pixel definition layer 380 is positioned on the anode. The pixel definition layer 380 having an opening OP exposing the anode and covering at least a portion of the anode may be positioned on the anode. The pixel definition layer 380 may be a black pixel definition layer formed of a black organic material to reduce or prevent the likelihood of light applied from the outside being reflected back to the outside, and may be formed of a transparent organic material in one or more embodiments. Therefore, according to one or more embodiments, the pixel definition layer 380 may include a negative-type black organic material and may include a black pigment.

A spacer 385 includes positioned on the pixel definition layer 380. Unlike the pixel definition layer 380, the spacer 385 may be formed of a transparent organic insulating material. According to one or more embodiments, the spacer 385 may be formed of a positive-type transparent organic material.

Functional layers FL1 and FL2 and the cathode are sequentially formed on the anode, the spacer 385, and the pixel definition layer 380. The light emission layer EML may be positioned between the functional layers FL1 and FL2, and the light emission layer EML may be positioned only in the opening OP of the pixel definition layer 380. Hereinafter, the functional layers FL1 and FL2 and the light emission layer EML may be combined to form an intermediate layer. The functional layers FL1 and FL2 may include at least one of auxiliary layers, such as an electron injection layer, an electron transport layer, a hole transport layer, and a hole injection layer. The hole injection layer and the hole transport layer may be positioned below the light emission layer EML, and the electron transport layer and the electron injection layer may be positioned above or on the light emission layer EML.

An encapsulation layer 400 may be positioned on the cathode. The encapsulation layer 400 includes at least one inorganic film and at least one organic film, and may have a triple-layer structure including a first inorganic encapsulation layer, an organic encapsulation layer, and a second inorganic encapsulation layer according to one or more embodiments. The encapsulation layer 400 may protect the light emission layer EML from moisture, oxygen, or the like that is introduced from the outside. Depending on one or more embodiments, the encapsulation layer 400 may include a structure in which an inorganic layer and an organic layer are sequentially stacked.

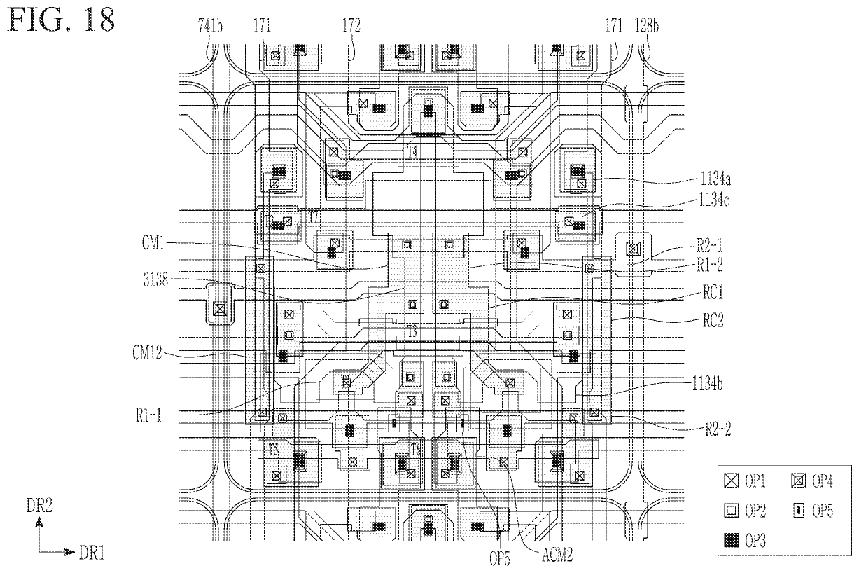

Hereinafter, a display panel according to one or more other embodiments will be described with reference to FIG. 18. FIG. 18 is a plan view of a display panel layer according to one or more other embodiments. Hereinafter, only descriptions of components different from the above-described components are included, and FIG. 18 may be a modification of embodiments corresponding to FIG. 14 described above. A first connection electrode CM1 and a twelfth connection electrode CM12 that are deformed as compared with FIG. 14 will be described in more detail with reference to FIG. 18.

The first connection electrode CM1 may include a (1-1)-th region R1-1 connected to the gate electrode 1151 of the first transistor T1 and a (1-2)-th region R1-2 connected to the third transistor T3. The (1-1)-th region R1-1 may be electrically connected to the gate electrode 1151 of the first transistor T1 through the first opening OP1. The (1-2)-th region R1-2 may be connected to the second region 3138 of the third transistor T3 and/or the second region 4138 of the fourth transistor T4 through the second opening OP2. Alternatively, the (1-2)-th region R1-2 may be connected to the upper boost electrode 3138t of the boost capacitor C_{boost} through the second opening OP2.

The (1-2)-th region R1-2 may cover the second region 3138 of the third transistor T3 extending in the second direction DR2. The second region 3138 may extend in the second direction DR2, and the (1-2)-th region R1-2 may have a form covering a portion of the second region 3138. For example, the (1-2)-th region R1-2 may overlap the second region 3138 of the third transistor T3 at a position that does not overlap the second gate conductive layer and the third gate conductive layer. The (1-2)-th region R1-2 may be spaced apart from the gate electrode 3151 of the third transistor T3 and the lower shielding layer 3155 of the third transistor T3 on a plane.

The (1-2)-th region R1-2 may be electrically connected to the third transistor T3 through two second openings OP2. The two second openings OP2 overlapping the (1-2)-th region R1-2 may be spaced apart from each other in the second direction DR2. Even if a micro-crack is generated in the third transistor T3 between the two second openings OP2, a connection of the transistor T3 may be maintained because the (1-2)-th region R1-2 are electrically connected through each second opening OP2.

The first connection electrode CM1 may include a first connection region RC1 connecting the (1-1)-th region R1-1 and the (1-2)-th region R1-2. The first connection region RC1 may have a shape extending substantially in the second direction DR2, but is not limited thereto, and may have any shape for connecting the (1-1)-th region R1-1 and the (1-2)-th region R1-2.

The second region 3138 of the third transistor T3 extending along the second direction DR2 may be vulnerable to a corresponding test (e.g., evaluation of stiffness against pen drop or the like) of the display device. In the second region 3138, a micro-crack may be generated during a corresponding inspection, when the display device is bent, or the like. In the display device according to one or more embodiments, the (1-2)-th region R1-2 of the first connection electrode CM1 may be connected to the second region 3138 of the third transistor T3 through at least two openings. Even if a portion of a path of the third transistor T3 is cut off, an electrical connection state may still be maintained through the (1-2)-th region R1-2 of the first connection electrode CM1.

The twelfth connection electrode CM12 may have a bar shape extending substantially along the second direction DR2. The twelfth connection electrode CM12 may overlap the second regions of the second transistor T2. For example, the second transistor T2 includes a first region 1134a electrically connected to the data line 171, a second region 1134b electrically connected to the first transistor T1, and a channel 1134c positioned between the first region 1134a and the second region 1134b. The channel 1134c may overlap the first scan line 151.

The twelfth connection electrode CM12 may include a (2-1)-th region R2-1, a (2-2)-th region R2-2, and a second connection region RC2. Each of the (2-1)-th region R2-1 and the (2-2)-th region R2-2 may overlap the second region 1134b of the second transistor T2. Each of the (2-1)-th region R2-1 and the (2-2)-th region R2-2 may be connected to the second region 1134b of the second transistor T2 through the first opening OP1. The second connection region RC2 may extend substantially in the second direction DR2 and may not overlap the second transistor T2 according to one or more embodiments. The second connection region RC2 may overlap the second region 1134b of the second transistor T2.

The second region 1134b of the second transistor T2 extending along the second direction DR2 may be vulnerable to a corresponding test (e.g., evaluation of stiffness against pen drop or the like) of the display device. A micro-crack may be generated in the second region 1134b during a corresponding inspection, when the display device is bent, or the like. In the display device according to one or more embodiments, each of the (2-1)-th region R2-1 and the (2-2)-th region R2-2 of the twelfth connection electrode CM12 may be connected to the second region 1134b of the second transistor T2. Even if a portion of a path of the second transistor T2 is cut off, an electrical connection state may still be maintained through the (2-1)-th region R2-1 and the (2-2)-th region R2-2 of the twelfth connection electrode CM12.

According to one or more embodiments, even if a disconnection occurs due to a crack in the first semiconductor layer or the second semiconductor layer, an electrical connection through a metal connection electrode positioned at a different layer from the first semiconductor layer or the second semiconductor layer is maintained so that the likelihood that a corresponding pixel is displayed due to a defective bright spot may be reduced or prevented, and the display device having improved reliability is provided.

While the present disclosure been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims, with functional equivalents thereof to be included therein.

Description of Some Reference Characters

| | |
|---|---|
| 110: substrate | ACT1: first semiconductor layer |
| GAT1: first gate conductive layer | GAT2: second gate conductive layer |
| ACT2: second semiconductor layer | GAT3: third gate conductive layer |
| V: valley | MTL: connection metal conductive layer |
| T1, T2, T3: transistor | CM1, CM12: connection electrode |
| R1-1: (1-1)-th region | R1-2: (1-2)-th region |
| R1-3: (1-3)-th region | RC1: first connection region |
| R2-1: (2-1)-th region | R2-2: (2-2)-th region |
| RC2: second connection region | OP1, OP2: opening |

What is claimed is:

1. A display device comprising:
a substrate;
a first semiconductor layer above the substrate, and comprising a first transistor and a second transistor;
a first gate conductive layer and a second gate conductive layer above the first semiconductor layer;
a second semiconductor layer above the second gate conductive layer, and comprising a third transistor;
a third gate conductive layer above the second semiconductor layer;
an insulating film defining a valley surrounding the first semiconductor layer, the first gate conductive layer, the second gate conductive layer, the second semiconductor layer, and the third gate conductive layer;
a connection metal conductive layer above the insulating film, and comprising a first connection electrode electrically connecting the first transistor to the third transistor, the first connection electrode comprising a (1-1)-th region overlapping the first transistor, and a (1-2)-th region and a (1-3)-th region overlapping the third transistor, the (1-2)-th region and the (1-3)-th region being connected to the third transistor; and
a first data conductive layer and a second data conductive layer above the connection metal conductive layer.

2. The display device of claim 1, wherein the first connection electrode comprises a first connection region connecting the (1-1)-th region and the (1-2)-th region, and
wherein the (1-3)-th region protrudes from the first connection region.

3. The display device of claim 2, wherein the (1-2)-th region and the (1-3)-th region are spaced apart from each other.

4. The display device of claim 2, wherein the (1-2)-th region and the (1-3)-th region protrude in a first direction, and
wherein the first connection region extends in a second direction that is substantially perpendicular to the first direction.

5. The display device of claim 2, wherein the third transistor comprises a first region, a second region, and a channel between the first region and the second region, and
wherein the (1-2)-th region and the (1-3)-th region are electrically connected to the second region of the third transistor.

6. The display device of claim 5, wherein the (1-2)-th region and the (1-3)-th region are connected to the third transistor through an opening.

7. The display device of claim 5, wherein the (1-2)-th region and the (1-3)-th region are spaced apart from the second gate conductive layer and the third gate conductive layer.

8. The display device of claim 1, wherein the connection metal conductive layer further comprises a twelfth connection electrode that comprises a (2-1)-th region and a (2-2)-th region overlapping the second transistor, and that comprises a second connection region between the (2-1)-th region and the (2-2)-th region.

9. The display device of claim 8, wherein the second transistor comprises a first region, a second region, and a channel between the first region and the second region, and
wherein the (2-1)-th region and the (2-2) region overlap the second region of the second transistor.

10. The display device of claim 9, wherein the (2-1)-th region and the (2-2)-th region are connected to the second region of the second transistor through an opening.

11. The display device of claim 8, wherein the second connection region is spaced apart from the second transistor.

12. The display device of claim 9, wherein the second transistor further comprises a protrusion overlapping the (2-1)-th region and the (2-2)-th region.

13. The display device of claim 1, wherein the connection metal conductive layer comprises at least one of gold (Au), silver (Ag), aluminum (Al), copper (Cu), platinum (Pt), and iron (Fe).

14. A display device comprising:
a substrate;
a first semiconductor layer above the substrate, and comprising a first transistor and a second transistor;
a first gate conductive layer and a second gate conductive layer above the first semiconductor layer;
a second semiconductor layer above the second gate conductive layer, and comprising a third transistor that comprises a first region, a second region, and a channel;
a third gate conductive layer above the second semiconductor layer;
an insulating film that comprises a valley surrounding the first semiconductor layer, the first gate conductive layer, the second gate conductive layer, the second semiconductor layer, and the third gate conductive layer;
a connection metal conductive layer above the insulating film, and comprising a first connection electrode electrically connecting the first transistor to the third transistor, the first connection electrode comprising a (1-1)-th region overlapping the first transistor and a (1-2)-th region covering the second region of the third transistor; and
a first data conductive layer and a second data conductive layer above the connection metal conductive layer.

15. The display device of claim 14, wherein the first connection electrode comprises a first connection region connecting the (1-1)-th region and the (1-2)-th region, and extending in a first direction, and
wherein the (1-2)-th region and the first connection region extend in a second direction that is substantially perpendicular to the first direction.

16. The display device of claim 15, wherein the third transistor comprises the channel between the first region and the second region, and
wherein the (1-2)-th region is electrically connected to the second region of the third transistor through at least two openings.

17. The display device of claim 15, wherein the (1-2)-th region is spaced apart from the second gate conductive layer and the third gate conductive layer.

18. The display device of claim 14, wherein the connection metal conductive layer further comprises a twelfth connection electrode that comprises a (2-1)-th region and a (2-2)-th region overlapping the second transistor, and a second connection region between the (2-1)-th region and the (2-2)-th region.

19. The display device of claim 18, wherein the second transistor comprises a first region, a second region, and a channel between the first region and the second region, and
wherein the (2-1)-th region and the (2-2)-th region are connected to the second region of the second transistor through an opening.

20. The display device of claim 18, wherein the second connection region overlaps the second transistor.
